(19) United States
(12) Patent Application Publication
(10) Pub. No.: US 2006/0157849 A1
(43) Pub. Date: Jul. 20, 2006

(54) Electronic component with semiconductor chip and semiconductor wafer with contact pads, and method for the production thereof

(76) Inventors: Bernd Goller, Otterfing (DE); Hermann Vilsmeier, Regensburg (DE)

Correspondence Address: EDELL, SHAPIRO & FINNAN, LLC, 1901 RESEARCH BLVD., SUITE 400, ROCKVILLE, MD, 20850, US

(21) Appl. No.: 11/337,084

(22) Filed: Jan. 23, 2006

Related U.S. Application Data
(63) Continuation of application No. PCT/DE04/01359, filed on Jun. 28, 2004.

(30) Foreign Application Priority Data
Jul. 22, 2003 (DE) DE 103 33 465.3

(51) Int. Cl. H01L 23/48; H01L 21/44

(52) U.S. Cl. 257/738; 257/E23.02; 438/613

(57) ABSTRACT

An electronic component with semiconductor chips and a semiconductor wafer with contact pads are described, as well as methods of forming such structures. The contact pads on the semiconductor chip include mesa structures that are dimensioned in such a way that they are adapted to the sizes of compression heads of bond connections and also exert a pressure-distributing effect on the upper side of the contact pads.

### CROSS REFERENCE TO RELATED APPLICATIONS

This application is a continuation of International Application No. PCT/DE2004/001359, filed on Jun. 28, 2004 and titled “Electronic component with semiconductor chip and semiconductor wafer with contact pads, and method for the production thereof,” and further claims priority under 35 USC §119 to German Application No. DE 103 33 465.3, filed on Jul. 22, 2003, and titled “Electronic component with semiconductor chip and semiconductor wafer with contact pads, and method for the production thereof,” the entire contents of which are hereby incorporated by reference.

### FIELD OF THE INVENTION

The invention relates to an electronic component with a semiconductor chip and to a semiconductor wafer with contact pads, and also to a method for the production thereof.

### BACKGROUND

Electronic components of a semiconductor wafer include contact pads that are arranged on an active upper side of the semiconductor chip including an integrated circuit and are in connection with electrodes of circuit elements of the integrated circuit by means of interconnects. Bonded on the contact pads are bonding wires, which connect the contact pads to contact terminal areas inside a component package. The contact terminal areas are for their part in connection with external terminals of the electronic component by means of contact vias through the component package.

The functionality of electronic components of this type depends on the reliability and the arrangement of the bond connections on the active upper side of the semiconductor chip. Impairment of the functionality of the integrated circuits by bond connections on contact pads can lead to the complete malfunctioning of the integrated circuit, if components of the integrated circuit are arranged under the contact pad with the applied bond connection. In order not to impair the functionality of the integrated circuit by bond connections, regions of the upper side under which there are no components of the integrated circuit are therefore provided on the active upper side of the semiconductor chip for contact pads. This has the consequence that, with an increasing number of contact pads, it is required that an increased amount of the upper side of the semiconductor chip cannot be used by the integrated circuit and this consequently makes the semiconductor chip more expensive.

### SUMMARY

An object of the invention is to provide an electronic component with which the semiconductor material under the contact pads can be used for arranging circuit elements of an integrated circuit without impairing the functionality of the electronic component by applying a bond connection.

This and other objects are achieved in accordance with the present invention by providing an electronic component that comprises a semiconductor chip with contact pads on an active upper side of the semiconductor chip including an integrated circuit. In addition, the electronic component comprises bond connections from the contact pads to contact terminal areas inside a component package. External terminals are in connection with the contact terminal areas inside the package by contact vias through the package. The contact pads are arranged on predetermined surface regions of the semiconductor chips under which circuit elements of the integrated circuit are arranged. In order for bond connections on the contact pads not to impair the circuit elements of the integrated circuit arranged thereunder as a result of microcracks and peak voltages in the semiconductor material, the contact pads include on their upper side pressure-distributing mesa structures, the dimensions of which are adapted to the sizes of compression heads of the bond connections.

As used herein, compression heads are understood as meaning the region of a bonding wire that is initially melted in the bonding process to form a “free air ball” and subsequently, in thermosonic bonding, pressed onto a contact pad on the upper side of the semiconductor chip at an elevated temperature (e.g., 150° C.-300° C.) and under pressure.

The pressure-distributing effect of the mesa structure provides the advantage that no microcracks are produced in the semiconductor material underneath the bond connection by the bonding pads and voltage peaks are reduced at an early time, since the compressive pressure does not extend from a first contact point in a punctiform manner but rather emanates from a bordering edge of the laser structure which has a pressure-distributing effect. For this purpose, the size of the mesa structure is adapted to the size of a bonding wire bead that has formed shortly before the bonding by incipient melting of the bonding wire and and during the bonding process forms a compression head, which is also known as a “nailhead”.

This bonding wire bead can have a diameter of from 35 μm to 50 μm with a wire diameter of from 18 μm to 25 μm. The mesa structure that is adapted to the size of the bonding wire bead then has a rising bordering edge with a mesa height of from 1 μm to 3 μm and an inner diameter of from 10 μm to 20 μm. A mesa structure of this type can cover the entire upper side of the contact pad apart from an inner area within the rising bordering edge or from a ring which has a width of between 2 μm and 10 μm. The rising bordering edge of the mesa structure surrounds a central depression in the direction of the upper side of the contact pad.

The adaptation of the size of this bordering edge to the size of the compression head can achieve the effect that the bonding wire bead is pressed onto the bordering edge either shortly before it is placed onto the central depression or as it is placed onto the central depression. In this case, the bordering edge may be of an oval, square, rectangular or polygonal form. In each case, the force that is exerted by the free air ball on the contact pads is distributed over a number of points on the upper side of the contact pads, so that a pressure-distributing effect emanates from the mesa structure on the contact pads.

In another embodiment of the invention, a semiconductor wafer is provided with semiconductor chip positions arranged in rows and columns, the semiconductor wafer including integrated circuits with contact pads in the semiconductor chip positions. The contact pads are arranged over circuit elements of the integrated circuit and include pressure-distributing mesa structures, the dimensions of which are adapted to the sizes of compression heads of bond connections.

On a semiconductor wafer of this type, more semiconductor chip positions than was previously possible can be provided, since no additional semiconductor material regions that are kept free from circuit elements have to be provided for the contact pads. This leads to a greater utilization of the active surface of a semiconductor wafer, in particular whenever the number of contact pads per semiconductor chip position increases. With the aid of the arrangement of contact pads according to the invention on the semiconductor wafer, the contact pads can also be arranged in a number of rows within a chip position, where the number of contact pads on the semiconductor wafer in the chip positions can be increased as desired without taking up any additional active upper side of the semiconductor wafer.

A method for producing a semiconductor wafer, in accordance with the invention, with semiconductor chip positions arranged in rows and columns includes the following method steps. First, a semiconductor wafer with integrated circuits in semiconductor chip positions is provided. Subsequently, a first patterned metal layer for contact pads is applied in the semiconductor chip positions over the circuit elements of the integrated circuit. Subsequently, a second patterned metal layer is produced on the contact pads, forming mesa structures on the upper sides of the contact pads. This method has the advantage that no additional semiconductor chip surface has to be made available for the contact pads, but instead the surface of the semiconductor wafer can be limited to the size of surface that is required for the integrated circuits in each semiconductor chip position. Consequently, the method produces a semiconductor wafer of which the upper side can be used more intensively than before for integrated circuits.

The application of a patterned metal layer to already existing metal contact pads takes place in a number of successive method steps. First, a closed photoresist layer is applied to the semiconductor wafer on the existing, already patterned first metal layer for contact pads; subsequently, the photoresist layer is patterned by exposing, developing and fixing the photoresist in such a way that the photoresist layer remains on regions of the semiconductor wafer that are not to be provided with an additional second metal layer for mesa structures. After the patterning of the photoresist layer, a closed second metal layer is then applied to the patterned photoresist layer.

In this connection, a closed metal layer or closed photoresist layer is understood as meaning a layer which initially covers the entire upper side of a semiconductor wafer. After applying the closed second metal layer, this metal layer is patterned. This stripping process, in which the stripping of a patterned photoresist layer brings about the removal of regions of the metal layer arranged on it from the upper side of a semiconductor wafer, is of advantage if metallic mesa structures can be applied to metallic areas, since there is no need for either a dry etching step or a wet etching step, which entail the risk that the already present upper side of the contact pad is etched or damaged. The material of the second metal layer may correspond to the metal of the contact pads or comprise some other, though bondable metal alloy.

Thus, special mesa structures at the center of a bonding pad or a contact pad have the effect that, when the incipiently melted bead or ball of the bonding wire impinges on the contact pad, the contact does not occur in a punctiform manner but instead contact over a surface area is obtained. These structures can have various geometrical forms, such as annular, square or octagonal, and form an elevation around a depression at the center of the pad. These mesa structures distribute the forces occurring during bonding over a larger area and consequently reduce the loading of the semiconductor material per unit area. In this way, the reduction of the compressive forces occurring makes it possible for bonding to be carried out without the risk of microcracks or “cracks” in the semiconductor chip regions underneath the pad metallization or the metallization of the contact pads.

The above and still further objects, features and advantages of the present invention will become apparent upon consideration of the following detailed description of specific embodiments thereof, wherein like numerals designate like components.

### BRIEF DESCRIPTION OF THE DRAWINGS

FIG. 1 depicts a basic diagram of the pressure-distributing effect of a mesa structure on a semiconductor pad.

FIG. 2 depicts by blackening the pressure-distributing effect of the mesa structure of FIG. 1.

FIG. 3 depicts a schematic representation of a bonding wire with a bonding wire bead before it is placed onto an annular mesa structure on a contact pad.

FIG. 4 depicts a plan view of the mesa structure of FIG. 3 in a first embodiment of the invention.

FIG. 5 depicts a plan view of the mesa structure of FIG. 3 in a second embodiment of the invention.

FIG. 6 depicts a schematic cross section through the bonding wire bead when it is placed onto the contact pad of FIG. 3.

FIG. 7 depicts a schematic plan view of a contact pad with a mesa structure of a third embodiment of the invention.

FIG. 8 depicts a schematic plan view of a contact pad with a mesa structure of a fourth embodiment of the invention.

FIG. 9 depicts a schematic plan view of a semiconductor chip with a mesa structure on the contact pads in accordance with the invention.

FIG. 10 depicts a schematic plan view of a semiconductor chip with a mesa structure on the contact pads, which are arranged in two rows on the upper side of the semiconductor chip, in accordance with the invention.

FIG. 11 depicts a schematic cross section through a contact pad on an upper side of a semiconductor chip including circuit elements formed in accordance with the invention.

FIG. 12 depicts a schematic cross section of the contact pad of FIG. 11 with a photoresist layer deposited on it.

FIG. 13 depicts the schematic cross section of the contact pad of FIG. 12 after exposure of the photoresist layer.

FIG. 14 depicts the schematic cross section of the contact pad of FIG. 13 after development of the photoresist layer.

FIG. 15 depicts the schematic cross section of the contact pad according to FIG. 14 after application of a second metal layer.

FIG. 16 depicts the schematic cross section of the contact pad of FIG. 15 after removal of the remains of the photoresist layer with the applied second metal layer.

### DETAILED DESCRIPTION

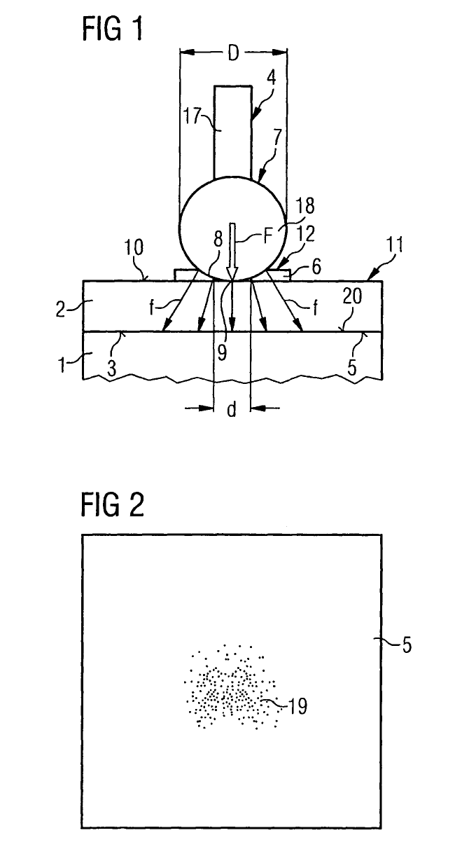

FIG. 1 shows a basic diagram of the pressure-distributing effect of a mesa structure 6 on a contact pad 2. In this embodiment of the invention, the contact pad 2 is arranged on an active upper side 3 of the semiconductor chip 1 and lies in a surface region 5 of the semiconductor chip 1 in which components of an integrated circuit are arranged in the semiconductor material of the semiconductor chip 1 underneath the rear side 20 of the contact pad 2. The contact pad 2 is part of a first patterned metal layer 11 for contact pads. Apart from the contact pads, this first patterned metal layer 11 also has interconnects to electrodes of the integrated circuit.

Arranged on the upper side 10 of the contact pad 2 is a mesa structure 6. Mesa structures 6 of this type rise up above the upper side of the semiconductor chip and have a height of between 1 μm and 3 μm. In this embodiment of the invention, this mesa structure 6 is of an annular form. A bonding wire 17 of a bond connection 4 is melted at its end to form a bonding wire bead. This bonding wire bead 18 is pressed onto the contact with a compressive force in the direction of the arrow F under ultrasonic excitation. This has the effect of forming a compression head 7, which is adapted in its size to the mesa structure in such a way that the annular mesa structure 6 has a smaller inner diameter d than the outer diameter D of the compression head 7. When the bonding wire bead 18 is lowered onto the mesa structure 6, the force acting in the direction of the arrow F will therefore not act on the contact pad 2 in a punctiform manner, but instead, on account of the contact of the bonding wire bead 18 and the rising bordering edge 8 of the mesa structure 6, the force becomes effective on the contact pad and on the rear side 20 of the contact pad 2 in the direction of the arrows f.

This pressure-distributing effect of the mesa structure 6 reduces mechanical stress peaks, so that no microcracks in the semiconductor material are produced in the region of the bond connections 4. It is consequently possible to arrange the contact pads 2 over circuit elements of the integrated circuit.

FIG. 2 shows by blackening 19 the pressure-distributing effect of the mesa structure 6 according to FIG. 1. A boundary layer between the rear side of the contact pad and the upper side region 5 of the semiconductor chip 1 is depicted. In this upper side region 5, circuit elements of an integrated circuit lie under the contact pad. These circuit elements are not damaged, because, as shown in FIG. 1, the force occurring during bonding is distributed over a larger surface area by the mesa structure on the contact pad. Consequently, the pressure on the bonding area or the contact pad and on the semiconductor chip material lying under it is decreased in such a way that the contact pads can then be arranged as desired on the active upper side of the semiconductor chip without regard for the integrated circuit.

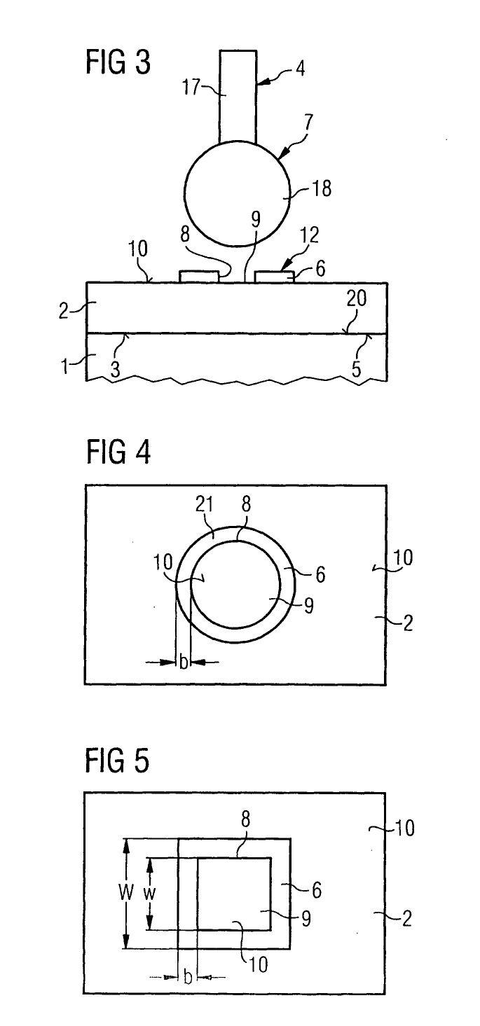

FIG. 3 shows a schematic representation of a bonding wire 17 with a bonding wire bead 18 before it is placed onto a mesa structure 6 on a contact pad 2. Components with the same functions as in the previous figures are identified by the same designations and are not separately explained. The contact pad 2 has a square size of from 30×30 μm² to 400×400 μm². This range preferably lies between 30'30 μm² and 100×100 μm². Applied to this contact pad is a smaller mesa structure 6, which has at its center a central depression 9 and has rising bordering edges 8, which come into contact with the bonding wire bead 18 at the same time as or shortly before the bonding wire bead 18 is placed onto the depression 9.

FIG. 4 shows a plan view of the mesa structure 6 of FIG. 3 in a first embodiment of the invention. This mesa structure 6 is of an annular form and has the upper side 10 of the contact pad 2 inside and outside the ring 21. The ring 21 has an inner radius of between 5 μm and 10 μm and an outer radius of between 10 μm and 25 μm. In the first embodiment of the invention according to FIG. 4, the width of the ring b lies between 2 μm and 10 μm.

FIG. 5 shows a plan view of the mesa structure of FIG. 3 in a second embodiment of the invention. Components with the same functions as in the previous figures are identified by the same designations and are not separately explained.

In this embodiment, which is shown in plan view in FIG. 5, the mesa structure is formed as a square ring. The width b of the second embodiment corresponds with the width b of the first embodiment. The inner edge w has a length of from 10 to 20 μm and the outer edge W lies between 20 and 50 μm. In this case, a width b for the ring structure of from 2 to 20 μm remains. The upper side 10 of the contact pad 2 is arranged both inside the mesa structure and outside the mesa structure.

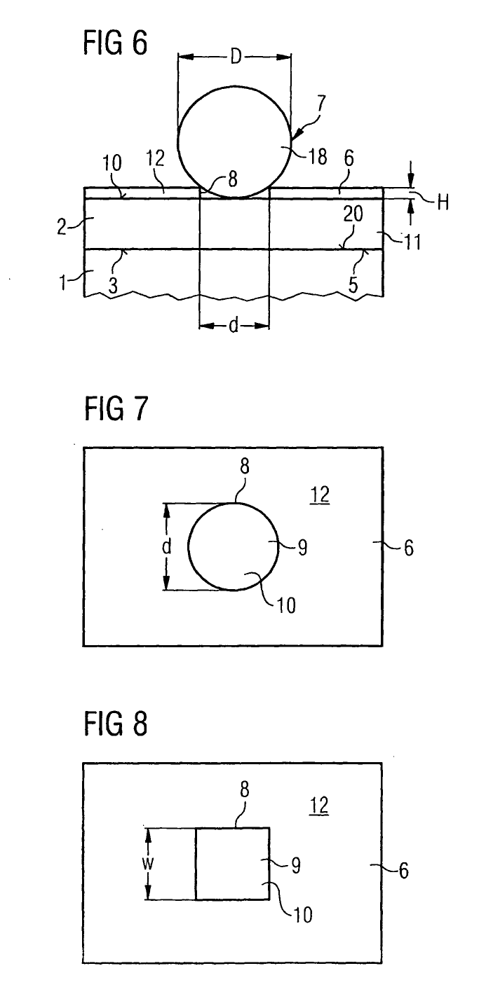

FIG. 6 shows a schematic cross section through a bonding wire bead 18 when it is placed onto the contact pad 2 of a third embodiment of the invention. In this embodiment, the mesa structure 6 covers the contact pad 2 completely, apart from a circular area with the diameter d. In this case, the diameter d is based on the diameter D of the bonding wire bead 18. Table 1 indicates the respective figures for two different diameters D of 40 μm and 50 μm. This is because the diameter d is adapted not only to the diameter D of the bonding wire bead 18, but also to the varying mesa height H, which in Table 1 comprises between 1 μm and 3 μm. In the case of 3 μm, the inner diameter d is at its greatest and, in the case of the mesa height H of 1 μm, the diameter d is at its smallest, with 12.5 μm and 14 μm, respectively, for the two different diameters D.

| | D = 40 μm | D = 50 μm |
|---|---|---|
| H (μm) | D (μm) | D (μm) |
| 1 | 12.5 | 14.0 |
| 1.5 | 15.2 | 17.1 |
| 2 | 17.4 | 19.6 |
| 2.5 | 19.4 | 21.8 |
| 3 | 21.1 | 23.7 |

FIG. 7 shows a schematic plan view of a contact pad with a mesa structure 6, which covers the entire upper side of the contact pad and merely leaves an annular depression 9 free at the center of the contact pad, reaching as far as the upper side 10 of the contact pad. This produces a bordering edge 8 rising up from the upper side 10 of the contact pad, ensuring that the pressure is distributed over the surface area when a bond connection is established.

FIG. 8 shows a schematic plan view of a contact pad with a mesa structure 6, which covers the entire upper side 10 of the contact pad apart from a central depression 9 at the center of the contact pad. The depression 9 at the center of the contact pad again reaches down as far as the upper side 10 of the contact pad. The bordering edge 8 rising up in a square manner has the same pressure-distributing effect as the annularly arranged bordering edge of the third embodiment of the invention shown in FIG. 7.

FIG. 9 shows a schematic plan view of a semiconductor chip 1 with mesa structures on the contact pads 2. The solid line 22 indicates the outer border of the semiconductor chip and is identical to the outer limit of the surface region with circuit elements of the integrated circuit. This means that the contact pads 2 are arranged over circuit elements of the integrated circuit.

The mesa structure on the contact pads 2, as shown in the previous figures, has the effect that the pressure on the contact pads during bonding is distributed in such a way that no microcracks occur in the monocrystalline semiconductor material lying under it, and consequently there is also no damage to the circuit elements of the integrated circuit arranged under it. The dashed line 23 identifies the size of the semiconductor chip 1 that would be required if there were no pressure-distributing mesa structure arranged on the contact pads 2. A larger surface is then required for the semiconductor chip 1 to accommodate the contact pads in the border region 16 of the semiconductor chip without a circuit arranged underneath the contact pads. This makes it possible to do without expensive silicon areas on a semiconductor wafer and for a greater number of semiconductor chips 1 to be accommodated per semiconductor wafer.

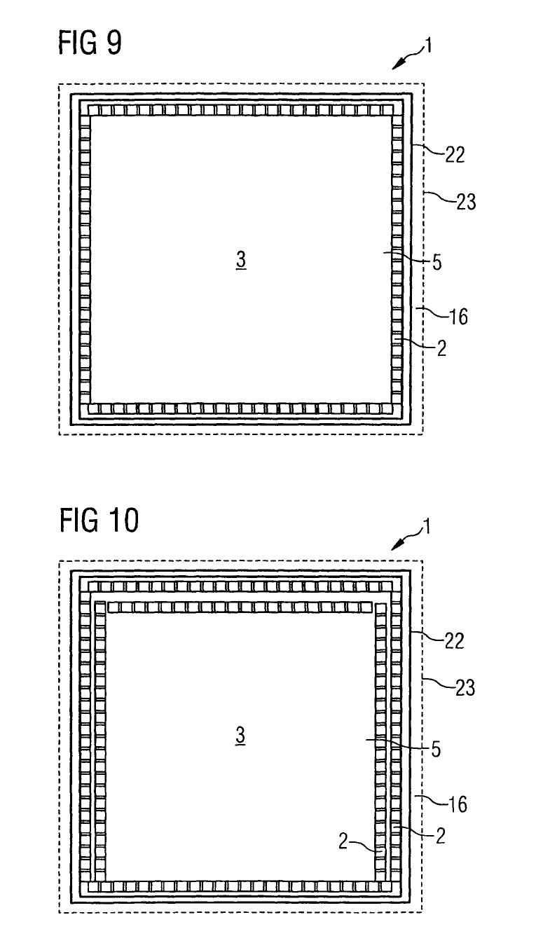

FIG. 10 shows a schematic plan view of a semiconductor chip 1 with mesa structures on the contact pads 2 which are arranged in two rows on the upper side 3 of the semiconductor chip 1. Consequently, in principle any number of rows of contact pads 2 can be arranged on the semiconductor chip 1 without the number of contact pads 2 increasing the requirement for semiconductor surface, since the contact pads 2 are arranged on circuit elements of the integrated circuit. The dashed line 23 indicates the size of the semiconductor chip 1 when the contact pads 2 do not have a mesa structure, and consequently require a surface region in addition to the surface region that has an integrated circuit.

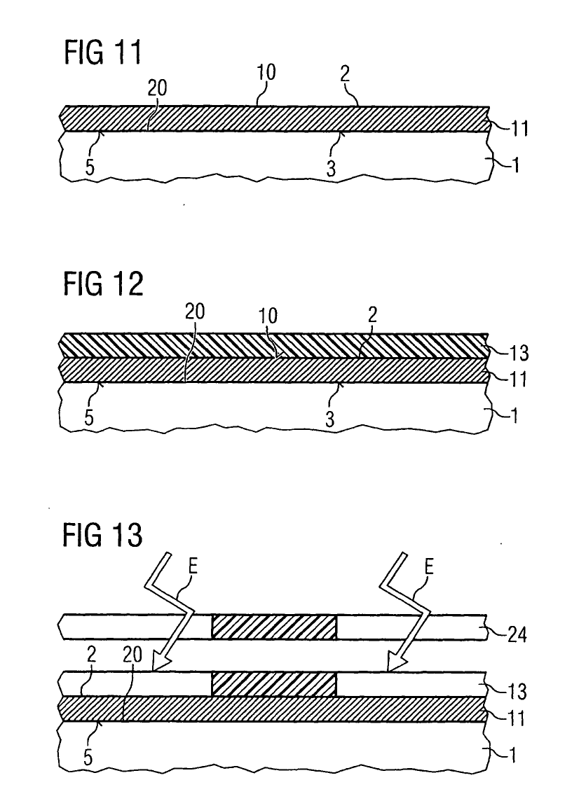

FIGS. 11 to 16 show schematic cross sections through a contact pad 2 which is to be patterned with a mesa structure 6 by applying a second metal layer 12.

FIG. 11 shows a schematic cross section through a contact pad 2 which is formed by a structured first metal layer 11. The contact pad 2 is positioned on a surface region 5 under which circuit arrangements of the integrated circuit are arranged.

FIG. 12 shows a schematic cross section of the contact pad 2 according to FIG. 11 with a photoresist layer 13 arranged on it. This photoresist layer 13 is closed and arranged on the entire upper side of a semiconductor wafer. Patterning has the effect that it remains on the semiconductor wafer wherever no additional second metal layer is to be applied. This patterning of the photoresist layer is shown in FIG. 13.

FIG. 13 shows the schematic cross section of the contact pad 2 according to FIG. 12 after exposure of the photoresist layer 13. This exposure in the direction of the arrow E takes place through a photomask 24, which is blackened at the locations at which the photoresist is not to be exposed.

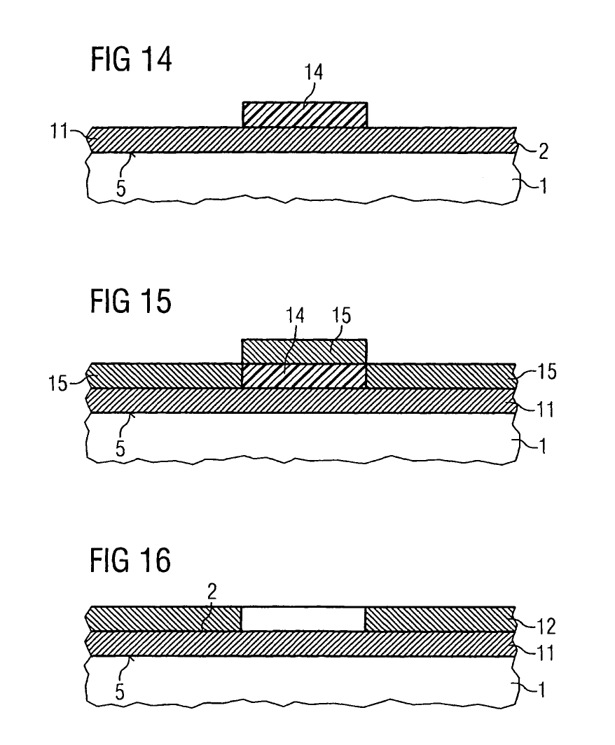

FIG. 14 shows a schematic cross section through the contact pad 2 of FIG. 13 after the development of the photoresist, the exposed region of the photoresist being dissolved during the development process.

FIG. 15 shows the schematic cross section of the contact pad 2 according to FIG. 14 after application of a second closed metal layer 15. In this case, the metal is deposited both on the contact pad 2, as a mesa structure, and on the patterned photoresist layer 14. By dissolving or ashing the photoresist 14, the metallization of the closed metal layer 15 located on the photoresist is stripped with the photoresist 14 from the contact pad 2.

FIG. 16 shows the schematic cross section of the contact pad 2 after removal of the remains of the photoresist layer with the then patterned second metal layer 12. This photolithography produces on each contact pad an appropriate mesa structure, which acts in a pressure-distributing manner when a bond connection is established on the contact pads 2.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. An electronic component comprising:
a semiconductor chip comprising an integrated circuit and contact pads disposed on an active upper side of the semiconductor chip;
bond connections extending from the contact pads to contact terminal areas inside a component package; and
external contacts that are electrically connected with the contact terminal areas;
wherein the contact pads are arranged on predetermined surface regions of the semiconductor chip under which circuit elements of the integrated circuit are arranged, and pressure-distributing mesa structures are disposed on upper sides of the contact pads, the dimensions of the mesa structures being configured to receive compression heads of the bond connections.

2. The electronic component of claim 1, wherein each mesa structure comprises a rising bordering edge that surrounds a central depression in the mesa structure and extending toward the upper side of the contact pad.

3. A semiconductor wafer with semiconductor chip positions arranged in rows and columns, the semiconductor wafer comprising integrated circuits with contact pads in the semiconductor chip positions, the contact pads being arranged over circuit elements of the integrated circuits and comprising pressure-distributing mesa structures having dimensions that correspond with compression heads of bond connections that connect with the contact pads and extend to contact terminal areas inside a component package.

4. A method for producing a semiconductor wafer with semiconductor chip positions arranged in rows and columns, the method comprising:
providing a semiconductor wafer with integrated circuits in semiconductor chip positions;
applying a first patterned metal layer to form contact pads in the semiconductor chip positions over circuit elements of the integrated circuits;
applying a second patterned metal layer on the upper sides of the contact pads and forming mesa structures from the second patterned metal layer.

5. The method of claim 4, wherein the application of the second patterned metal layer and forming mesa structures comprises:
applying a closed photoresist layer to the semiconductor wafer;
patterning the photoresist layer by exposing, developing and fixing the photoresist on regions of the semiconductor wafer that are not to be provided with an additional second metal layer for forming mesa structures;
applying a closed second metal layer to the patterned photoresist layer such that regions of the second closed metal layer are disposed on the photoresist layer;
patterning the closed second metal layer by stripping the patterned photoresist layer with the regions of the second closed metal layer disposed on the photoresist layer; and
removing the photoresist layer.

6. The method of claim 4, further comprising:
separating the semiconductor wafer into semiconductor chips;
applying a semiconductor chip to a component carrier;
producing bond connections between the contact pads of the semiconductor chip and contact terminal areas of the component carrier by forming compression heads on the mesa structures of the contact pads of the semiconductor chip; and
embedding the bond connections and the semiconductor chip in a plastic package molding compound.
